(19) United States
(12) Patent Application Publication
(10) Pub. No.: US 2009/0173082 A1
(43) Pub. Date: Jul. 9, 2009

(54) NOVEL SOLID STATE THERMOVOLTAIC DEVICE FOR ISOTHERMAL POWER GENERATION AND COOLING

(76) Inventor: Matthew Rubin, Indianapolis, IN (US)

Correspondence Address: Brannon & Associates PC, 1 North Pennsylvania Street, Suite 520, Indianapolis, IN, 46204, US

(21) Appl. No.: 12/333,891

(22) Filed: Dec. 12, 2008

Related U.S. Application Data
(60) Provisional application No. 61/013,718, filed on Dec. 14, 2007.
(60) Provisional application No. 61/028,731, filed on Feb. 14, 2008.
(60) Provisional application No. 61/092,215, filed on Aug. 27, 2008.

(51) Int. Cl. F25B 21/02; H01L 35/30; F25B 27/00

(52) U.S. Cl. 62/3.3; 62/3.2; 136/205; 62/238.1

(57) ABSTRACT

A device for simultaneously generating electrical power and cooling, including an active layer for intrinsically transducing thermal energy into electrical energy, a first electrical contact having a first work function and a second electrical contact having a second work function, a first electron diffusion barrier positioned between and in electric communication with the active layer and the first electrical contact, and a second electron diffusion barrier positioned between and in electric communication with the active layer and the second electrical contact. The first work function and the second work function are nonidentical. Transduction of thermal energy into electrical energy yields thermally generated electrical carriers of both positive and negative charge, wherein thermally generated electrical carriers are separated according to charge to either the first electrical contact or the second electrical contact, thereby lowering the average thermal energy of the active layer.

### CROSS-REFERENCE TO RELATED APPLICATIONS

This patent application claims priority to co-pending U.S. Provisional Patent Application Ser. No. 61/013,718, filed Dec. 14, 2007; U.S. Provisional Patent Application Ser. No. 61/028,731, filed Feb. 14, 2008; and U.S. Provisional Patent Application Ser. No. 61/092,215, filed Aug. 27, 2008.

### TECHNICAL FIELD

This novel technology relates generally to the field of energy transduction, and, more specifically, to the direct conversion of thermal energy into electrical energy.

### BACKGROUND

Direct thermal to electrical energy conversion devices (“DTE devices”) have been of commercial interest for many years. DTE devices conventionally utilize temperature gradients to motivate electrical carriers through an electrically conductive medium to generate usable electrical power. Temperature may be operationally defined as the average energy of the motions of particles per degree of freedom in a system, and thermal energy is the type of energy that may be added or subtracted from a system or material to change its temperature. Conventional wisdom acknowledges that two systems of two different temperatures placed in thermal communication will generate a temperature gradient across the material interface. Thermal energy will then diffuse from the system of higher temperature to the system of lower temperature until a thermal energy equilibrium is reached. Power generation in DTE devices is generally understood to be proportionate to the size of the device, the magnitude of the temperature gradient, and the intrinsic efficiency of the device. Conventional DTE devices cease to produce usable electrical power once the thermal energy equilibrium is reached. Reestablishing the temperature gradient across the system reinitiates electrical power production. Examples of DTE devices include Peltier and thermoelectric devices, thermionic devices, and thermophotovoltaic devices.

DTE devices are known to have several commercial advantages over mechanical devices including small size, few to no moving parts, long life, and high reliability. However, high cost and low thermodynamic efficiency are two common disadvantages of DTE devices. Low thermodynamic efficiencies which produce thermal losses in DTE devices commonly arise from several sources, including competitive thermal and electrical conduction processes, destructive recombination of charge carriers, and internal electrical resistance.

Conventionally, DTE devices utilize materials with high electrical conductivity to reduce internal electrical resistance. Conventional high electrical conductivity materials also commonly exhibit high thermal conductivity. Examples of these materials include iron, nickel, copper, silver, gold, aluminum, platinum, and magnesium. Such materials are less attractive for DTE devices since their high thermal conductivities allow them to come to thermal equilibrium quickly, thereby rapidly reducing the thermal gradient necessary for the generation of electrical power. To decrease the effect of competing thermal and electrical conduction processes and thus extend their effective operational life, DTE devices often take advantage of complex materials which have high electrical conductivities but low thermal conductivities, such as bismuth telluride and lead telluride.

Thermophotovoltaic devices have been designed to address thermal losses common to DTE devices by placing a black body emitter and a photo-collector in the system. Unfortunately, ideal black body emission temperatures often overlap with the melting temperature of the collector. Common strategies to prevent collector melting include utilizing thermal separators and additional heat sinks to maintain the black body emitter and photo-collector at different constant temperatures while keeping them in close physical proximity to one another. This strategy creates a temperature potential across the system and is known to be a source of significant thermodynamic losses. The photo-collectors are also commonly known to be characterized by significant internal losses resulting from nonradiative photo-carrier recombination.

Cooling may be defined as the process of lowering the temperature of a system by removing thermal energy. Non-chemical cooling methods conventionally utilize a refrigeration cycle which transfers thermal energy from a lower temperature heat source to a higher temperature heat sink. This method requires an energy input to drive the transfer of thermal energy from a lower temperature source to a higher temperature sink and thus establishes a temperature gradient between the heat source and heat sink which naturally diffuses across the system. To maintain a constant temperature at the heat source the system must either receive a continuous input of energy or disconnect the thermal communication between the heat source and heat sink. The process of disconnecting and thermally isolating refrigeration systems is conventionally very difficult, often rendering a continuous input of energy as the preferred alternative.

Conventional DTE devices use an electrically powered refrigeration cycle to cool a system. Due to their relatively small size, DTE devices are often unable to move heat significant distances, and as a result are commonly combined with secondary heat transport systems, such as a mechanical fan, to move the thermal energy away from the heat sink. This strategy typically adds complexity and cost to the overall system.

One unique advantage of DTE devices is their ability to readily act as either a refrigeration cycle or an electrical power generator, depending on whether an electric potential or a temperature gradient is applied to the device. However, DTE devices have not enjoyed widespread use beyond semiconductor processor and infrared photodetector cooling, because of their relatively low thermodynamic efficiency compared to conventional mechanical compressor/evaporator refrigeration cycles.

It is known that intrinsically semiconductive materials produce thermally generated electrical carriers at room temperature, resulting from a phonon/exciton equilibrium, and that the number of thermally generated carriers per unit volume is understood to be proportionate the temperature and the material properties of the semiconductor (most notably the bandgap) as shown in FIG. 1. It is also known that the generation rates of thermally generated carriers can be affected by intrinsic semiconductor properties, crystal defects, and material impurities. While thermally generated carriers have been used in limited applications to improve the refresh rates of high speed MOS circuits and photo-detectors, thermally generated carriers are more commonly considered to be a nuisance. In the majority of semiconductor devices, thermally generated carriers are either ignored or intentionally avoided, often through the addition of complexity to device designs and/or the lowering of the device operating temperature.

The use of asymmetric electrical contacts is well known in the art. Asymmetric contacts commonly consist of two different electrically conductive materials of different work functions which contact the same semiconductor at different locations, generating an electric field through the semiconductor between the contacts, similar to a depletion region in a PN junction. Typically, the built-in potential for asymmetric electrical contacts is equal to the difference between the work functions of the two contacts. However, impurities in semiconductors are known to lower the built-in potential by producing a charged dipole layer near the contacts, as shown in C60 doped organic polymer solar cells, thereby lowering the useful voltage of the device. These junctions are often governed by drift-diffusion equilibriums and have exhibited useful applications in organic photovoltaic devices and MSM photodetectors. Asymmetric electrical contacts may be deposited using a number of conventional techniques include patterned physical vapor deposition (PVD), photolithography, chemical vapor deposition (CVD), and the like.

Thermoelectric and thermionic diffusion processes allow electrical carriers to overcome small electrical barriers, and it is known that Schottky barriers of less than about 0.4 eV at room temperature are not sufficiently high to prevent electrical carrier diffusion across a system and electrical equilibrium formation.

Electron tunneling is the quantum process whereby electrons pass through barriers that would be normally impenetrable under classical physics. Electron diffusion barriers sufficiently thin to allow electron tunneling are known in the art and have been frequently exploited in applications such as MIS photovoltaic cells and nonvolatile semiconductor memory devices. Electron diffusion barriers have also previously been used to prevent dark current in photodetector devices and have been fabricated by several conventional processes including plasma enhanced chemical vapor deposition (PECVD), atomic layer deposition (ALD), and ultra-thin film oxidation.

Various materials, such as Al and Ti, are known in the art to grow natural barrier oxides through ambient oxidation to thicknesses and band gaps consistent with electron diffusion barriers. The thicknesses of these native barriers have been controlled to the nanometer scale using conventional atmospheric oxidation techniques to regulate the partial pressure and temperature of the oxidizing gas in contact with the material surface, or conventional anodization techniques regulating the anodic potential of the material in contact with a pH neutral aqueous solution. Valve metals are one class of materials known in the art to form impermeable native barrier oxides from ambient oxidation, and may include Si, Al, Ta, Ti, Zr, Nb, and the like. Valve metals are commonly used in anodized coatings.

The tunnel magnetoresistance effect (TMR) is a process that creates changes in electrical resistance relative to the electron-spin orientation of two ferromagnetic materials separated by an electron diffusion barrier about 1-2 nm thick. TMR devices are known in the art and have been used in magnetic random access memory (MRAM).

Methods of electrochemical deposition of various metal oxides via cathodic and anodic techniques in aqueous environments are known in the art and may utilize either electrophoretic or electrolytic processes. Anodic deposition may grow ultra-thin metal oxides in valve metals and the like by motivating ion migration across a native barrier oxide layer under high electrostatic fields in aqueous environments. This method is known to produce oxide thicknesses directly proportionate to the applied voltage and is used in the production of electrolytic capacitors. For example, aluminum is known to grow approximately 1.3 nm of barrier oxide in an aqueous solution of ammonium borate for each volt applied to the anode, enabling reliable reproduction of ultra-thin oxides within nanometer tolerances.

Anodic electrochemical deposition of metal oxides from aqueous solutions are known in the art to result from destabilizing metal-ligand complexes near the anode surface, as shown in alkaline copper tartrate deposition of CuO, or by oxidizing a soluble metal ion, as shown in the acidic electrodeposition of MnO₂. Both of these methods lead to hydrolysis and precipitation of metal-oxides or metal-hydroxides at the electrode surface, and have been used extensively in the manufacturing of electrochemical energy cells or batteries.

Cathodic electrochemical deposition of metal oxides and metal hydroxides from aqueous solutions are known in the art to result from either electrochemical generation of base, as shown in Al(OH)₃ deposition from 5 mM Al(NO₃)₃ solutions at 1 mA/cm², or by changing the oxidation state of a soluble cation, which is insoluble due to hydrolysis. These methods have been used to electrodeposit device quality thin layers of Fe₃O₄ from a pH 13 ferric sulfate-triethanolamine (TEA) alkaline solutions at 60° C. under 5 mA/cm². These methods are also known in the art to deposit ultra-thin metal oxides from aqueous metal-nitrate solutions.

All of these DTE devices require a thermal gradient to generate electrical power, and electrical power generation efficiency increases with the magnitude of the thermal gradient so imposed. Thus, there remains a need for a DTE-type device that does not require a thermal gradient for the generation of electrical power. The present novel technology addresses this need.

### SUMMARY

The present novel technology relates generally to the direct conversion of thermal energy into electrical energy through thermal recycling, and, more particularly, to the use of low bandgap semiconductors, electron diffusion barriers, and asymmetric electrical contacts to achieve high efficiency operation in isothermal environments. One object of the present novel technology is to provide an improved method of electrical energy generation. Related objects and advantages of the present novel technology will be apparent from the following description.

### BRIEF DESCRIPTION OF THE DRAWINGS

FIG. 1 is a graph of the prior art showing the intrinsic carrier concentration vs. bandgap of a semiconductor at 300K.

FIG. 2 is a calculated graph showing electron tunneling current density at 300K for various tunnel barrier thicknesses between 11 to 12 Angstroms at a built in potential of 1.135 V across each tunnel junction.

FIG. 3 is a calculated graph showing electron tunneling current density at 300K for various tunnel barrier thicknesses between 11 to 17 Angstroms at a built in potential of 1.135 V across each tunnel junction.

FIG. 4 is a diagrammatic representation of the theoretical band diagram of an ITD device showing representative carrier generation, transfer, and tunneling processes.

FIG. 5 is a side view of an ITD device according to the present disclosure.

FIG. 6 is a diagrammatic representation of a Multilevel Active Layer.

FIG. 7 is a top view of one embodiment an ITD device utilizing interdigitated electrical contacts.

FIG. 8 is a side view of a multilayer ITD device.

FIG. 9 is a calculated graph of the current density vs. bandgap of a 200 nm thick ITD device at 300K.

FIG. 10 is a calculated graph of the current densities and electron tunneling current capacities for an ITD device according to the present novel technology for a 0.21 eV bandgap active layer device 200 nm thick at given temperatures and Active Layer carrier lifetimes.

FIG. 11 is a calculated graph of the current densities and electron tunneling current capacities for an ITD device according to the present novel technology for a 0.25 eV bandgap active layer device 200 nm thick at given temperatures and Active Layer carrier lifetimes.

FIG. 12 is a calculated graph of the current densities and electron tunneling current capacities for an ITD device according to the present novel technology for a 0.275 eV bandgap active layer device 200 nm thick at given temperatures and Active Layer carrier lifetimes.

FIG. 13 is a flow chart representative of a fabrication process of multiple embodiments of the present novel technology on a continuous substrate.

FIG. 14 is a diagrammatic representation of a water distillation system incorporating an ITD device.

FIG. 15 is a side view of an ITD thermal-electrical energy storage device.

FIG. 16 is an Eh-pH diagram of Fe ions in aqueous solution.

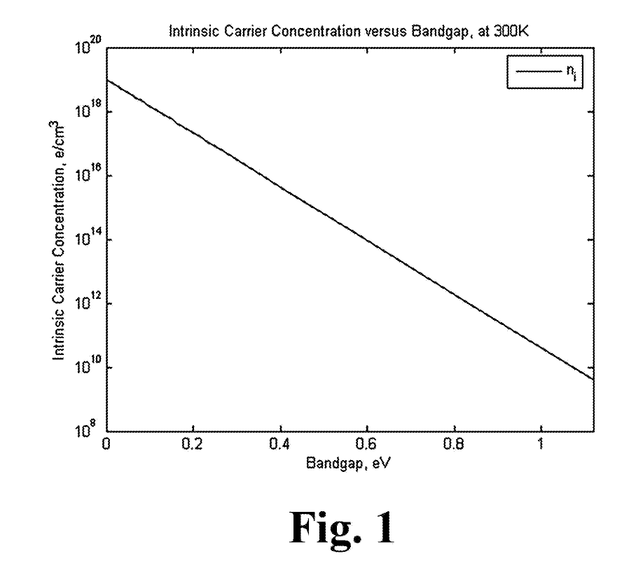

### DETAILED DESCRIPTION

For the purposes of promoting an understanding of the principles of the novel technology and presenting its currently understood best mode of operation, reference will now be made to the embodiments illustrated in the drawings and specific language will be used to describe the same. It will nevertheless be understood that no limitation of the scope of the novel technology is thereby intended, with such alterations and further modifications in the illustrated device and such further applications of the principles of the novel technology as illustrated therein being contemplated as would normally occur to one skilled in the art to which the novel technology relates.

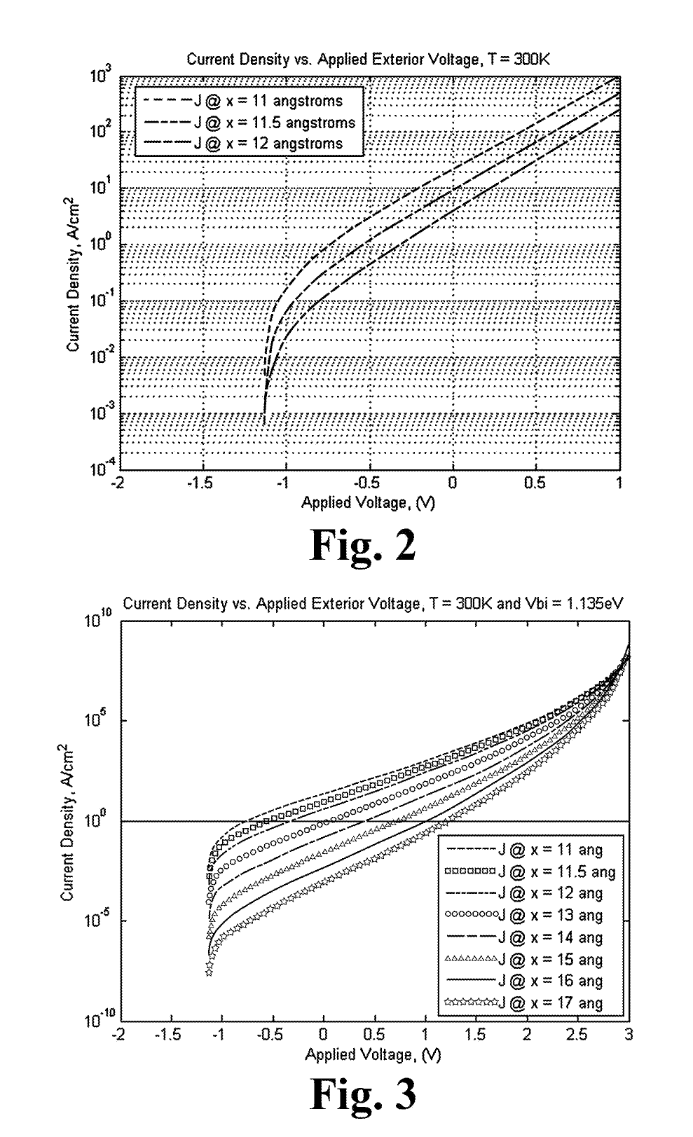

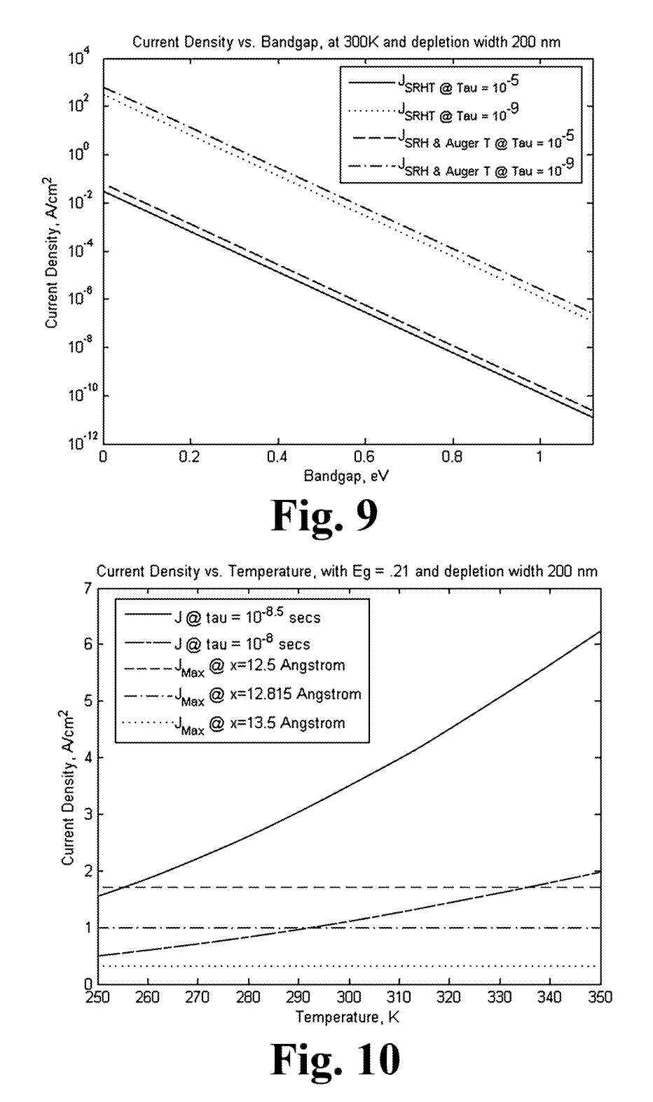

The present novel technology, as illustrated in FIGS. 2-16, relates to a method and devices for the direct conversion of thermal to electrical energy via cooling a heat source. In other words, the devices of the present technology use ambient thermal energy to produce electrical current without the requirement of a temperature gradient across the device, thus producing electrical power along with a coincident cooling of the device itself; this cooling effect may be exploited for refrigeration use while the generated electrical power may be utilized for any convenient electrical need or stored for later use. The present novel technology utilizes intrinsic processes in low bandgap semiconductors to convert thermal energy into electrical carriers, which are separated by asymmetric electrical contacts via a tunneling electron diffusion barrier. The novel technology is thus a process for high efficiency thermal recycling which enables thermal to electrical energy transduction under previously unproductive conditions, i.e., without the requirement of a thermal gradient in the transducer device. In addition, multiple devices may be layered in thermal series to achieve greater power densities for a given surface area and to exploit wider operating temperature ranges. The novel technologies disclosed hereinbelow may serve as a platform technology for energy storage, water distillation and desalination, refrigeration and cooling, air conditioning, and the like.

The novel technology enables transducer devices that are more efficient and economical, addressing many of the above-stated problems inherent in known DTE and refrigeration cycle devices. The known devices conventionally rely on temperature gradients to generate electrical power, or on the input of additional energy to achieve cooling. The present novel technology is discussed herein and embodiments are referred to for convenience as isothermal thermovoltaic devices (“ITD devices”). These devices are isothermal insofar as they do not require a pre-existing temperature gradient in order to produce electricity, even though in operation they inherently produce a cooling effect as they generate electrical power. Some applications are presented herein as examples of overcoming many of the disadvantages of previous DTE devices by utilizing the recycling of thermal losses to produce electrical power in the absence of a temperature gradient. This counterintuitive design incorporates an intrinsic thermal to electrical energy phase change governed by an equilibrium to recapture previously unused thermal losses and express them as useful electrical power. In addition, instead of moving thermal energy directly to provide cooling, the present ITD device absorbs thermal energy and transduces it into electrical energy, generating improved thermal transport properties over previous devices. In the most general case, an ITD device comprises an active layer, which intrinsically produces thermally generated electrical carriers, in electrical communication with two electrical contacts of different work functions, and an electron diffusion barrier between the active layer and each electrical contact. More specifically, the novel technology provides a practical alloy system for room temperature silicon-based and flexible-substrate-based ITD devices yielding substantial thermodynamic efficiency increases over both conventional DTE and refrigeration cycle devices. In addition, the novel technology provides a practical design suitable for fabrication using atmospheric pressure chemical vapor deposition (“APCVD”) of room temperature ITD devices and electrochemical fabrication of low temperature ITD devices.

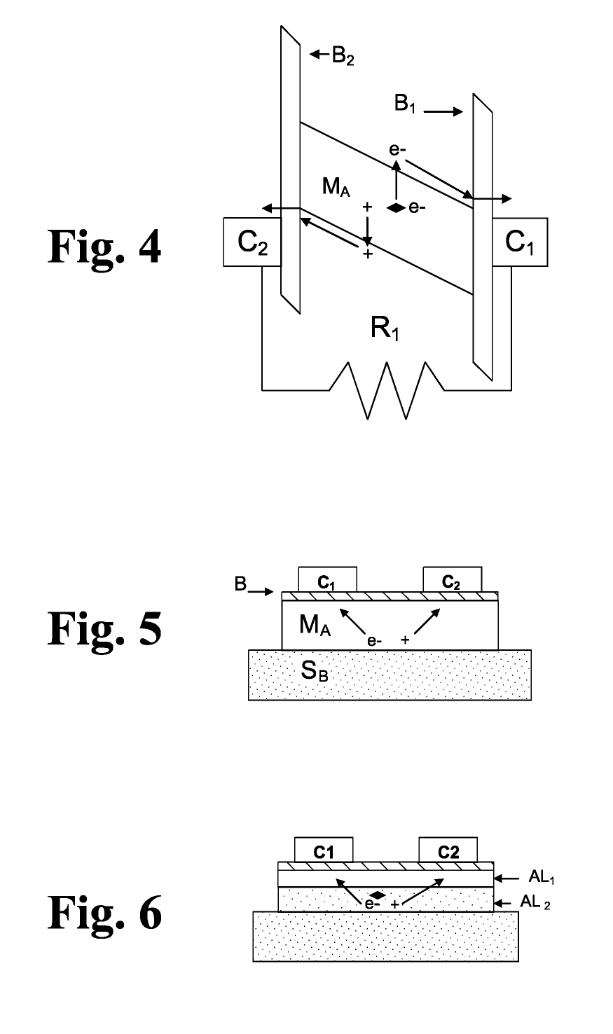

As illustrated in FIG. 4, an ITD device operates as follows: thermal energy present in the Active Layer (M_{A}) generates electrical carriers (e− and h+), which are separated according to charge type by the built in or intrinsic electric field (shown by the downward angle of the Active Layer) provided by the asymmetric electrical contacts (C₁ and C₂). These carriers drift towards electron diffusion barriers (B₁ and B₂) which separate and define the Active Layer, and the electrical carriers within, from the electrical contacts (C₁ and C₂). Assisted by the electric field, the charge carriers tunnel through the electron diffusion barriers (B₁ and B₂) and collect on the electrical contacts (C₁ and C₂). Collected charges will then either accumulate on the electrical contacts diminishing the built-in electric field until an equilibrium is reached, and thereby creating an open circuit potential, or diffuse through a separate resistive electrical circuit (R₁) thereby performing work while moving thermal energy from the ITD device to the resistive electrical circuit R₁. Resistive electrical circuits may be defined herein as any electrical network that completes an electrical circuit with at least one ITD device and transfers electrical energy either from the ITD device(s) to the electrical network, or alternatively, from the electrical network to the ITD device(s). The electrical resistance of the circuits may be conventionally ohmic, or may be exotic, such as an inductive resistance generated by a superconducting coil, or the like. The electrical power so produced by the ITD device increases with increasing device temperature up to the limits imposed by the device, such as its maximum tunneling current as governed by its built-in potential by the electron diffusion barriers B₁ and B₂.

Active Layers of the present novel technology may include any material which thermally generates sufficiently large populations of intrinsic electrical carriers at an intended operating temperature. At 300K, Active Layers may include low bandgap semiconductors and alloys of various atomic ratios with bandgaps typically between about 0.025 eV and about 0.60 eV, more typically between about 0.025 eV and about 0.40 eV, and still more typically between about 0.14 and about 0.40 eV. Such materials include SnₓSi_{y}Ge_{1-x-y}, SnₓGe₁₋ₓ, InSb, PbS, PbSₓSe_{y}Te_{1-x-y}, InₓGa₁₋ₓSb, InₓGa₁₋ₓAs_{y}Sb_{z}P_{1-y-z}, HgₓCd₁₋ₓTe, and the like. Active Layers may also be made from of low bandgap metal oxides, such as MnO₂, very low bandgap metal oxides, such as Fe₃O₄ and Ti₂O₃, and various low bandgap metal silicides, such as CrSi₂. Metal oxide Active Layers may enable ITD devices to be produced using electrochemical or APCVD manufacturing techniques. The use of Fe₃O₄ and Ti₂O₃ may also enable ITD devices to operate at temperatures significantly lower than 300K, or at higher than usual electron current factors (as defined hereinbelow) at 300K. In addition, Fe₃O₄ may improve device efficiency by taking advantage of TMR.

Low Temperature CVD growth of binary SnₓGe₁₋ₓ and ternary SnₓSi_{y}Ge_{1-x-y} alloys directly onto silicon wafer substrates using SnD₄, Ge₂H₆ (di-germane), SiH₃GeH₃, and (GeH₃)₂SiH₂ sources is known in the art. SnₓGe₁₋ₓ and ternary SnₓSi_{y}Ge_{1-x-y} alloy fabricating techniques have been shown to reliably generate device quality semiconductor structures on silicon substrates. Some of these devices include strain engineered quantum-well photodetectors, quantum well laser emitters and modulators, and transistors. The crystal quality of these devices has been confirmed using high-resolution electron microscopy, x-ray diffraction (“XRD”), and atomic force microscopy.

APCVD of Ti₂O₃ on 450-500° C. substrates (such as Al₂O₃, SiO₂, or the like) using direct liquid injection of solutions containing approximately a 1:50 ratio by volume of titanium(IV) tetraisopropoxide (“TTIP”) dissolved in tetrahydrofuran (“THF”) under the flow of argon is known in the art. Crystal composition using this deposition method has been confirmed using XRD. Lower deposition temperatures and/or the use of solvents other than THF often lead to the deposition of TiO₂ rather than Ti₂O₃. It is known that the surface of Ti₂O₃ may be oxidized to TiO₂ in atmospheric oxidizing environments, such as 550° C. air with water vapor content greater than 750 ppm or in anodic aqueous electrochemical environments.

Crystal defects and crystal impurities may be added to the Active Layer using several techniques to increase the generation rate of thermally generated electrical carriers, such as low temperature growth, high energy particle bombardment, the introduction of midlevel trap impurities that act as generation centers, and the like. Generation rates on the order of 1×10⁻⁸S to 1×10⁻⁹S can be readily attained using current growth techniques. Generation rates faster than 1×10⁻⁹S may enable the use of higher bandgap and higher power density ITD devices with similar electrical current density characteristics to low bandgap systems. The product of the Active Layer's intrinsic carrier concentration and its depth divided by the Active Layer's thermal carrier generation rate for the ITD device, here referred to as the electrical current factor, may typically be in range of between about 1×10¹⁷ and about 1×10²² e/cm²S at the intended operating temperature. As shown in FIG. 10, tradeoffs in material properties relating to these three variables may be made to optimize ITD device performance.

Electron diffusion barriers (B) typically comprise of a material with a sufficiently large bandgap to prevent significant electron diffusion, such as SiO₂, Si₃N₄, SiNₓO₁₋ₓ, SiC, TiO₂, Nb₂O₅, HfO₂, ZrO₂, Ta₂O₅, Fe₂O₃, WOₓ, MgO, Y₂O₃, and Al₂O₃. Typically electron diffusion barriers (B) are between 0.8 nm-3.0 nm thick. These barriers may be deposited using various techniques, such as PECVD and ALD. Electron diffusion barriers may also be grown on various materials, such as Ti and Al, to the desired thickness using conventional oxidation methods. As shown in FIG. 2 and FIG. 3, with a 1.135V built in potential at each electron diffusion barrier (which may be obtained, for example, by using Pt and Mg asymmetric electrical contacts), a SiO₂ layer of thicknesses less than 1.28 nm thick may be used to allow 1A/cm² of electrically generated carriers to be removed from the Active Layer under zero applied external bias. Multiple strategies, such as increasing surface roughness of the Active Layer, may be used to increase oxide thickness while maintaining sufficiently high current capacities in ITD devices. More complicated electron diffusion barriers, such as resonant tunnel barriers, may also be used to generate asymmetric electrical currents in ITD devices.

ITD device electrical contacts may be selected from “pure” metals, such as Au, Ag, Ni, Pt, Cr, W, Mn, Mg, Mo, Al, Fe, Ti, Ta, Ce, Hf, Zr, Nb, Th, Pb, Zn, Y, Pd, Ca, C, Li, Cu, alloys of “pure” metals, such as NiCr, LiₓAl₁₋ₓ, CaₓAl₁₋ₓ, MgₓAl₁₋ₓ, conductive metal oxides, such as indium oxide, lanthanum nickel oxide, indium tin oxide, cadmium oxide, cupric oxide, cuprous oxide, zinc oxide, aluminum zinc oxide, copper aluminum oxide, and like oxides, organo-metallic and metal-halide electrode bilayers, such as cathodes comprised of ultrathin lithium acetylacetonate or calcium acetylacetonate layers between the electron diffusion barrier and the aluminum or silver metal contacts, metal carbonates, such as Cs₂CO₃, or other convenient metals, oxides, or compounds. Electrical contacts may also consist of a various silicides, such as PtSi, P+ and N− silicon layers, or conductive nitride-metal alloys, such as titanium nitride.

It is known that metal alloys can change their work function as a result of atomic migration during thermal cycling. This property has been used to decrease the work function of the surface of an argon plasma etched LiₓAl₁₋ₓ alloy, where x equals about 0.065, down by −900 mV upon heating the alloy in an ultrahigh vacuum to 500K. The composition of the surface alloy after heating to 500 K and cooling to room temperature was approximately Li_{0.18}Al_{0.82}. This method may be used to decrease the work function of a valve metal, such as aluminum, alloyed with any one or multiple low work function elements, such as Mg, Ca, Y, Li, Na, Sr, and the like. Heating the alloy to a temperature sufficiently high to motivate atomic migration in an inert atmosphere, such as argon, after the formation of a protective surface oxide of a desired thickness may be used to produce a buildup of low work function metal atoms at the surface of the metal between the surface oxide and the bulk metal alloy, thereby forming a stable high bandgap electron diffusion layer between the ambient atmospheric environment and the low work function metal surface layer.

One embodiment of the instant device, as shown in FIG. 4, may be fabricated in a simple layered design wherein the first electrical contact (C₁) serves as the substrate for additional layers. This contact C₁ may be composed of a relatively low work function material, such as Al or Mg, which may grow a natural electron diffusion barrier (B) as a result of ambient oxidation. Alternately, contact C, may serve as the substrate for a first electron diffusion barrier (B₁) deposition. Next, an Active Layer (M_{A}) is deposited on the first barrier (B₁) and characterized by a sufficiently operational thickness, followed by the deposition of a second barrier (B₂), and finally a second electrical contact (C₂) composed of a relatively high work function material, such as Pt or Au. The two respective electrical contacts (C₁ and C₂) may then be connected in electric communication to a resistive electrical circuit (R₁). Alternatively, the relatively high work function contact (C₂) may serve as the substrate for additional layers, where device layers would be deposited in the reverse order as with the embodiment described above. In either embodiment described above, the substrate electrical contact may be deposited on supporting rigid substrates, such as doped silicon wafers, or on supporting flexible substrates, such as stainless steel foil, electrically conductive plastic, or the like. The use of supporting substrates may serve as a barrier to optical and chemical degradation, and may allow the use of thin layers of the electrical contacts without decreasing the structural integrity of the ITD device.

It is known that impurities in semiconductors lower the built-in potential of an asymmetric metal junction by producing charged dipole layers near the electrical contacts. Another embodiment of the present ITD device, as shown in FIG. 6, may utilize an asymmetric impurity doped Multilevel Active Layer (“ML-AL”). An ML-AL is comprised of at least one relatively high impurity Active Layer (AL₂), at least one relatively low impurity Active Layer (AL₁), and at least one electron diffusion barrier, where a low impurity Active Layer, typically at least about 5 nm thick, separates the relatively high impurity Active Layer from the electron diffusion barrier. If two independent electron diffusion barriers are utilized in the ML-AL ITD device, then at least two relatively low impurity Active Layers may be used to separate the high impurity Active Layer from each electron diffusion barrier, where asymmetric positioning of the relatively high impurity Active Layer between the electrical contacts may be used to compensate for inefficiencies resulting from differences in electron and hole drift current velocities. The use of an ML-AL may prevent the formation of an electric dipole at the Active Layer/electron diffusion barrier interface and may provide advantages over conventional Active Layers with uniform impurity distributions, such as increased carrier lifetimes at the tunneling interface and device open circuit voltages. An extreme example of an ML-AL may include at least one substantially metallic interlayer separating semiconductive Active Layers in electrical communication with the electron diffusion barriers.

One composition suitable for an ML-AL may be low and high impurity SnₓSi_{y}Ge_{1-x-y} and SnₓGe₁₋ₓ Active Layers, where the impurities may be metals of the group consisting of Zn, Ni, Cu, Ag, Au, Cr, Pt, Pd, Fe, or any combinations thereof. One method of fabricating these compositions may be to combine volatile molecules containing the desired impurity, such as copper dihexafluoroacetylacetonate (hfac), with the volatile germanium and tin source gases during CVD growth processes. This method may allow the impurity concentrations to be controlled for each deposition layer. Unlike low temperature fabrication and ion bombardment methods, impurity doped Active Layers may undergo multiple rapid thermal annealing cycles without significantly decreasing their electron generation rates. The concentrations of impurities in the high impurity active layer may typically fall into the range of 1×10¹²-1×10¹⁵ atoms/cm³.

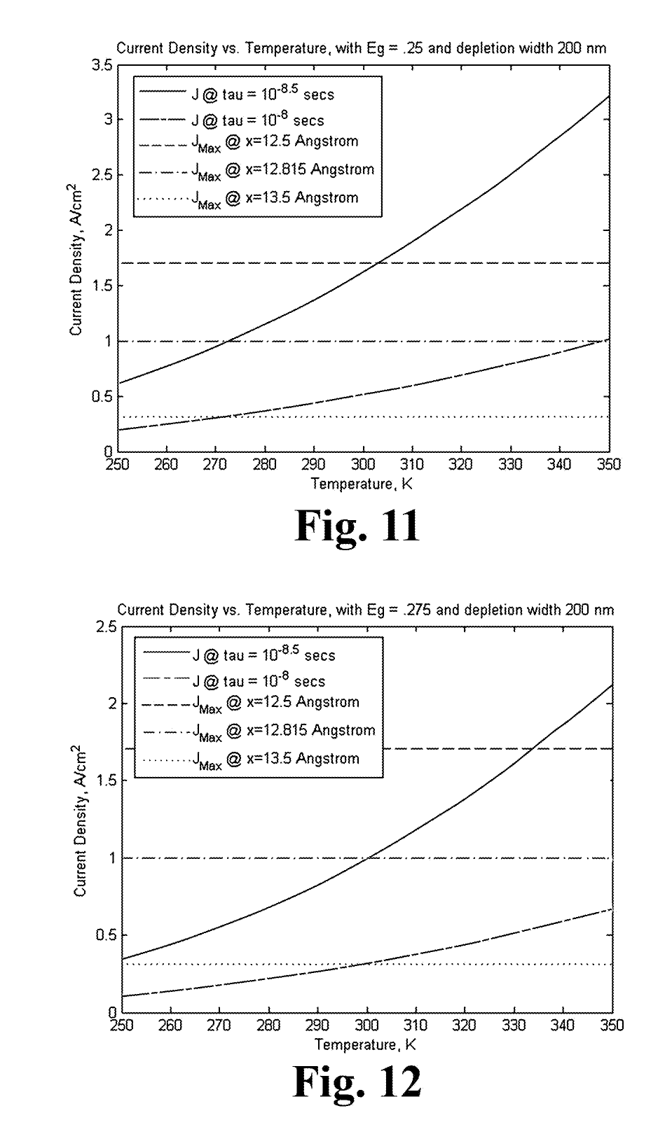

As shown in FIG. 5, another embodiment of the present novel technology typically intended for operation at about 300K may use an Active Layer (M_{A}), typically between about 20 and about 1000 nm thick, deposited on a silicon substrate base (S_{B}). The Active Layer may be formed of either SnₓGe₁₋ₓ, where x equals about 0.02 to about 0.25, or a SiₓSn_{y}Ge_{1-x-y}, where x equals up to about 0.25 and y equals about 0.02 to 0.30, with a bandgap between 0.15 eV and 0.60 eV and a carrier generation rate between about 1×10⁻⁸S and about 1×10⁻¹⁰S. An electron diffusion barrier (B) comprising of a suitable dielectric, such as SiO₂, typically between 1-2 nm thick, is then deposited on the Active Layer opposite the silicon substrate. This deposition is subsequently followed by the deposition and patterning of the first electrical contact material (C₁) followed by the second contact material (C₂) where one electrical contact material is formed of a high work function material, such as Pt or Au, and the other electrical contact material is formed of a low work function material, such as Mg or Al. Electrical wires may then be connected in electric communication to the asymmetric contacts to connect the device to a resistive electrical circuit. Additional buffer layers may be incorporated to prevent strain between the components, such as a layer of SnxSiyGel-x-y between the Active Layer and the substrate. In this embodiment, the silicon substrate base (S_{B}) may also serve as an efficient thermal conductor between the ITD device and the thermal energy source, and additional substrate coatings, such as polycrystalline diamond, may be used to improve thermal conductivity of the substrate-thermal energy source interface. As shown in FIG. 10, FIG. 11, and FIG. 12, useful quantities of electrical current may be produced by the ITD device of this embodiment having various Active Layer bandgaps, isothermal operating temperatures, and/or carrier generation rates.

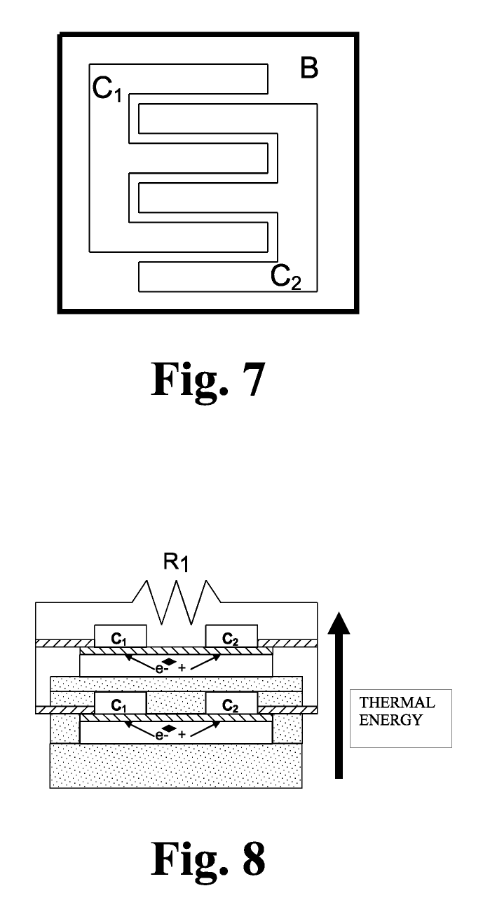

As shown in FIG. 7, yet another embodiment of the present technology, for a given size and shape, may use interdigitated electrical contacts to increase device efficiency. Interdigitated electrical contacts may increase the field strength in the Active Layer, increase the surface area of the electrical contacts, and decrease the series resistance of the ITD device, which may result in more efficient collection of the thermally generated carriers.

As shown in FIG. 8, multiple ITD devices may be stacked thermally in series to further increase their electrical power and cooling densities for a substrate surface area. This may be achieved by depositing substrate inter-layers, such as silicon, between fabricated and wired ITD devices, as described above. Subsequent smoothing techniques, such as chemical mechanical polishing, may be applied to the substrate inter-layers to improve the consistency among stacked ITD devices. Additional heat pipes, or vertical columns of high thermal conductivity material, which transcend across multiple layers of a stacked multi-ITD device may be used to further assist in device performance by improving thermal conductivity between the stacked ITD devices and decreasing material strain resulting from temperature gradients between the material layers.

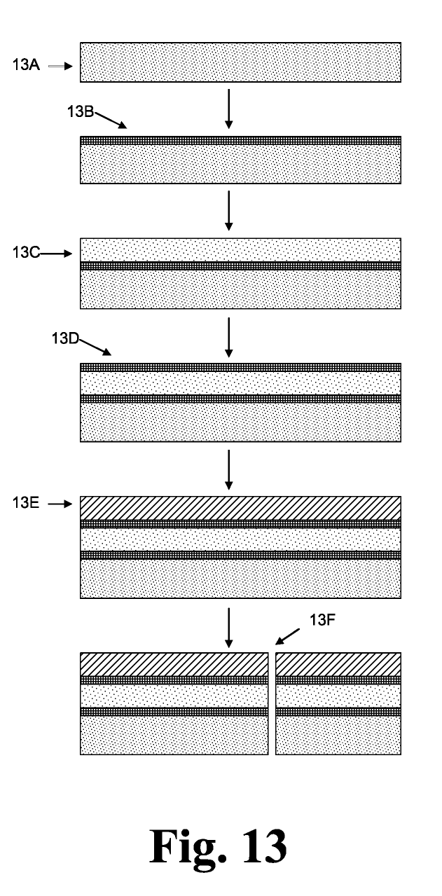

As shown in FIG. 13, multiple process steps may be used to fabricate an ITD device on a continuous, typically flexible, substrate. Fabrication typically begins with a suitable thermally and electrically conductive substrate (13A), such as stainless steel foil, aluminum foil, or the like. This substrate may serve as the first asymmetric electrical contact of the ITD device, or may serve as the substrate for the deposition of a secondary or subsequent electrical contact, such as gold or aluminum. In the case of aluminum foil substrates, the substrate may serve as the first asymmetric electrical contact and deposition of a secondary electrical contact may not be necessary. In the case of stainless steel foil substrates, deposition of a secondary electrical contact with a different work function, such as gold or aluminum, may be desired to increase device efficiency. These secondary electrical contacts may be deposited directly on the substrate using conventional deposition processes, such as physical vapor deposition or sputtering, or may be deposited on an electrically conductive buffer layer, such as SnO₂, chemically separating the substrate from the secondary electrical contact. The first electron diffusion layer (13B), such as SiO₂, may be deposited on the first asymmetric electrical contact using conventional deposition methods, such as PECVD. Alternatively, the first asymmetric electrical contact may grow a natural electron diffusion barrier from ambient oxidation, as in the case of aluminum foil. This may be followed by the deposition of the Active Layer (13C), such as Ge₁₋ₓSnₓ, followed by the deposition of the second electron diffusion barrier (13D) and followed by the deposition of the second asymmetric electrical contact (13E) of a composition and work function different from the first asymmetric electrical contact. The continuous ITD device may then be patterned into discrete devices (13F) using conventional methods, such as laser scribing, and may be followed by side passivation of the scribed regions by an electrically insulating material, such as SiO₂.

Similar to FIGS. 13A-13F and the above example, multiple process steps may be used to fabricate ITD devices via APCVD techniques. Similar continuous substrates, or alternatively discrete substrates, may be used and the sequence of deposition may proceed in a similar order. Fabrication typically begins with a suitable thermally and electrically conductive substrate (13A), such as stainless steel foil, Al foil, LiₓAl₁₋ₓ alloy, CaₓAl₁₋ₓ alloy, YₓAl₁₋ₓ, alloy, or the like. This substrate may serve as the first asymmetric electrical contact of the ITD device, or may serve as the substrate for the deposition of a secondary or subsequent electrical contact, such as YₓAl₁₋ₓ, or CaₓAl₁₋ₓ alloys. The use of a low work function material as the first asymmetric electrical contact, such as a CaₓAl₁₋ₓ alloy, may enable the growth of a native electron diffusion barrier (13B) from ambient oxidation, electrochemical anodization, or the like. This may be followed by the deposition of the Active Layer (13C), such as Ti₂O₃. This may be followed by the oxidation of the Active Layer to form the second electron diffusion barrier (13D) and followed by the deposition of the second asymmetric electrical contact (13E) of a composition and work function different from the first asymmetric electrical contact, such as CuO or Ni. The ITD device may be patterned into discrete devices (13F) either during fabrication using conventional methods, such as shadow masks, or alternatively after fabrication is complete using methods, such as laser scribing, and may be followed by side passivation of the scribed regions by an electrically insulating material, such as SiO₂.

CuO is a black p-type semiconductor with a known work function of about 5.3 eV. Multiple techniques have been developed to deposit CuO on metal oxide substrates, such as APCVD and flame assisted chemical vapor deposition (FACVD). One method of CuO APCVD begins by heating a suitable copper precursor, such as copper acetylacetonate (Cu(acac)₂), inside the deposition chamber to its sublimation temperatures, such as 145-190° C. in the case of Cu(acac)₂, in a continuous flow of oxygen. The Cu(acac)₂ vapor is then carried and deposited on a metal oxide substrate of a suitable temperature, such as 300° C. Alternatively, CuO may be deposited on a metal oxide covered substrate, such as TiO₂, of a suitable temperature, such as 400° C., using FACVD where an aqueous solution of a suitable concentration, such as 0.5 M Cu(NO₃)₂, is nebulised through a propane/oxygen flame in a noble carrier gas, such as N₂, onto the substrate. The crystallinity of both deposition methods has been confirmed elsewhere using XRD.

Ni may be deposited using similar techniques, such as atmospheric pressure metal organic CVD, where a source gas, such as Ni(acac)₂, is heated to sublimation in a flow of a noble gas, such as N₂, and then mixed with a flow of a reducing gas, such as H₂, and deposited on a 250-300° C. substrate, where the ratio by volume of the reducing gas to noble gas is at least 1:1.

Similar to FIGS. 13A-13F and the above example, multiple process steps may be used to fabricate ITD devices via electrochemical methods. Similar continuous substrates, or alternatively discrete substrates, may be used and the sequence of deposition may proceed in a similar order. Regulating the potential and current density of the opposite electrode to the substrate in each deposition bath and fixing the substrate to electrical ground may enable the use of continuous flexible substrates to simultaneously be in contact with multiple deposition baths at the same time. In addition, conventional electrochemical masking techniques may be used to produce patterned ITD devices on one or multiple sides of the substrate. Some of the benefits of electrochemical deposition over other deposition techniques include its ability to produce ITD devices on complex-shaped substrates and proceed under ambient open-air conditions. Combinations of electrochemical and solid-state fabrication techniques may also be combined to produce ITD devices.

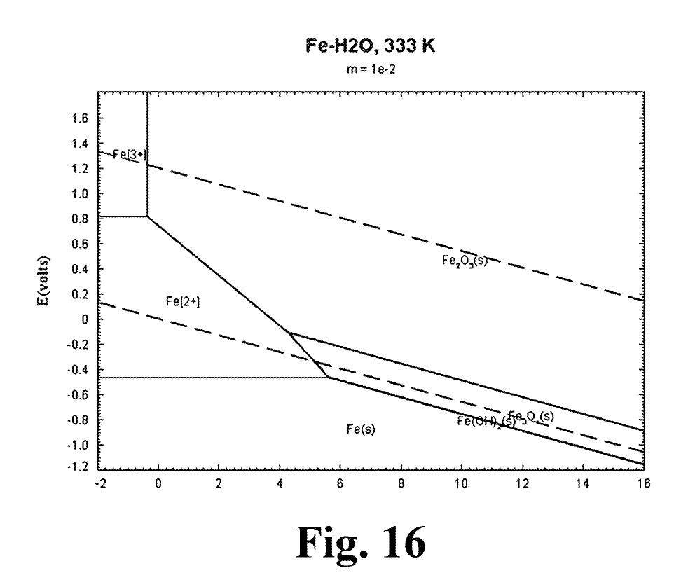

One example for fabricating an electrochemically deposited ITD device may begin with a suitably cleaned valve metal substrate, such as n-type amorphous or crystalline silicon. N-type silicon with a relatively low work function is sufficiently electropositive to serve as the first asymmetric electrical contact. N-type silicon also grows a native oxide between 1-2 nm, like many other valve metals, that is insoluble in most alkaline and acidic solutions and may serve as the first electron diffusion barrier. A subsequent Active Layer, such as Fe₃O₄, may be deposited on the native oxide using cathodic processes. Fe₃O₄ may be deposited using cathodic techniques from an alkaline aqueous solution of 0.09 M Fe^{(III)}, 0.1 M-TEA, and 2 M NaOH under galvanostatic conditions of 3-8 mA/cm² at 50-80° C., as supported by FIG. 16. Fe₃O₄ may also grow a native oxide of Fe₂O₃ that may serve as the second electron diffusion barrier and substrate for the second asymmetric electrical contact.

If other materials that do not produce a native oxide, such as MnO₂, are used as the active layer, then subsequent electron diffusion barriers may be deposited using anodic or cathodic electrochemical deposition. ZrO₂ for example may be cathodically electrodeposited from a 5 mM solution of zirconium nitrate under galvanostatic conditions of 1-3 mA/cm2.

Subsequent high work function asymmetric electrical contacts may be produced by cathodic or anodic deposition. In the case of cathodic deposition, a suitable electronegative material, such as nickel or Cu₂O, may be deposited using conventional techniques. In the case of anodic deposition, a suitable electronegative material, such as CuO, may be deposited using conventional techniques. Alternatively, the asymmetric electrical contact may be deposited using conventional electroless methods, as in the case of electroless nickel plating. Device quality CuO and Cu₂O for example may be deposited under galvanostatic conditions of 1-10 mA/cm² from the same alkaline aqueous solution of 0.2 M tartaric acid, 0.2 M CuSO₄, and 3 M NaOH at 60° C.

One application of an ITD device is in the field of cooling and power generation. In this embodiment, an ITD device is placed in either direct thermal communication with the desired medium to be cooled, such air or water, or indirect thermal communication via an intermediate thermal conductor. In the case of indirect thermal communication, the base substrate of the ITD device may be used as an effective thermal contact pad to transmit thermal energy efficiently from the intermediate thermal conductor. Indirect communication with the desired medium may have several advantages, such as greater control of thermal diffusion throughout the ITD device and chemical isolation from the desired medium, which may assist to improve device operational lifetime. Once in thermal communication with the desired medium, thermal energy may be absorbed by the ITD device and transferred electrically away from the ITD device via a resistive electrical circuit. During this process, the ITD device's temperature will decrease and a temperature gradient will be formed between the medium and the ITD device. Thermal energy will then diffuse from the medium to the ITD device, either indirectly or directly, thereby lowering the temperature of the medium. This process may continue until the medium reaches the desired temperature, at which time, the ITD device may be deactivated using conventional methods, such as increasing the electrical resistance of the circuit connecting the asymmetric electrical contacts. Additional thermal energy may be added to the medium which will subsequently diffuse to the ITD device, if the primary purpose of the system is to generate electrical power.

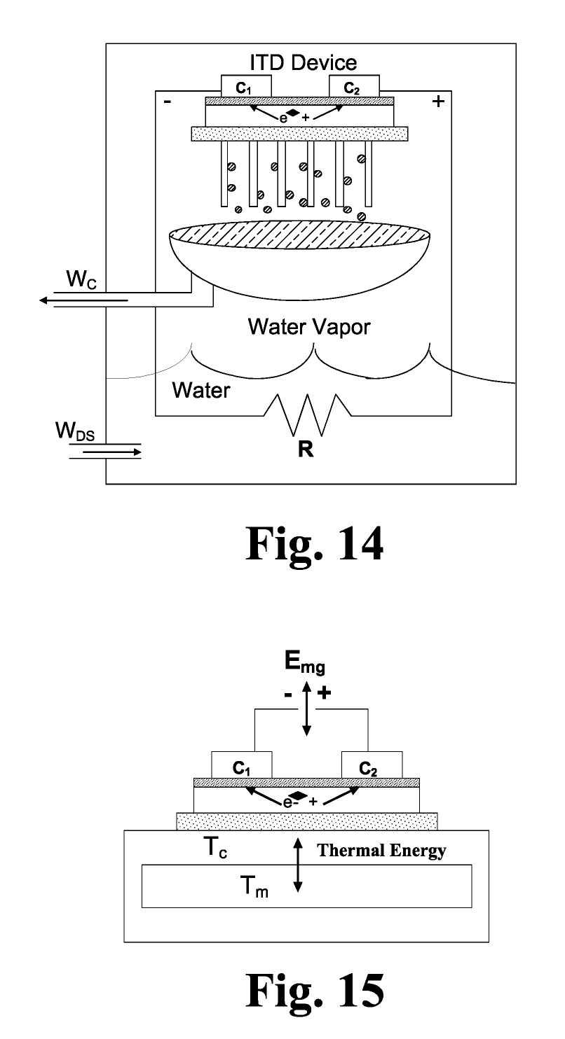

Another application of an ITD device is in the field of distillation, dehumidification, desalination, and air conditioning. As shown in FIG. 14, a water distillation device incorporating an ITD device may be made in its simplest form where water enters the system and is held in a water reservoir. Thermal energy is then provided to the water reservoir via a resistive electrical circuit (R), powered by the ITD device, which motivates a phase change from water to water vapor. The water vapor is then condensed into a water distillate using thermal conductors cooled by the ITD device, and then gravitationally driven down to a platform where the water distillate may be collected and transported out of the system. Distillate byproducts remaining in the water reservoir as a result of the distillation process may be discarded using additional plumbing (not shown) or may diffuse through the input water pipe. This device may similarly be used to distill other like liquids.

A dehumidification or an air conditioning device incorporating an ITD device may be made similarly to a water distillation device, except the resistive electrical circuit (R) is placed in a location that is not in significant thermal communication with a water reservoir. In a dehumidification device, the resistive circuit (R) may be placed in a location that is in significant thermal communication with the surrounding air, and in an air conditioning device, the resistive circuit (R) may be placed in a location that is not in significant thermal communication with the surrounding air. In an air conditioning device the electrical energy may also be converted into a relatively stable nonthermal form, such as chemical energy, that maintains thermal communication with the conditioned air. The resistive circuit (R) in an air conditioning device incorporating an ITD device may comprise of electrical circuitry of sufficient complexity to allow the generated electrical energy to be placed on a commercial network of power lines used to deliver electricity to inhabited areas (“Power Grid”). This electrical circuitry may typically comply with IEEE 1547 standards, or like standards, and may allow a third party to monitor the transfer of electrical energy from the air conditioning device to a Power Grid. While the above has been discussed specifically regarding the removal of water vapor from air, any first fluid may be likewise removed from a second fluid having a lower condensation temperature, and solid distillates may be preferentially removed according to the fluids' different ionic concentrations.

One application of a combined dehumidification/air conditioning ITD device is in the field of confined atmosphere agricultural systems, often referred to as greenhouses. Greenhouses rely on the use of sunlight or artificial light sources to provide optical stimulation of the biological material; however the majority of the optical energy is converted into heat rather than chemical energy, creating a disruption in the atmospheric temperature and/or humidity equilibriums. External ventilation or conventional refrigeration cycle devices are often used to reestablish the ideal atmospheric conditions, often requiring that the greenhouse receive the input of additional energy to maintain ideal optical, temperature, and humidity levels in the confined environment. One or multiple ITD device(s) in the confined environment may be electrically connected via a continuous monitoring and regulating system to a plurality of resistive electrical circuits including a circuit in the confined environment in significant thermal communication with a water reservoir, such as a humidifier, a circuit in the confined environment in significant thermal communication with the environment and not in thermal communication with a water reservoir, such as a light bulb or resistive heating element, and a circuit not in significant thermal communication with the confined environment, such as a Power Grid, thereby allowing continuous monitoring and regulation of the optical, temperature, and humidity levels of the confined environment while maximizing the energy efficiency of the system. Likewise, this system may be applied to removing heat from a freezer while simultaneously supply power to a grid or directly to other appliances (such as a dishwasher, a clothes washer, a clothes dryer, or the like), to cooling an internal living space, or the like.

While many of the prior applications and benefits of an ITD device discuss its cooling capacity, ITD devices also have the ability to generate heat, similar to an ohmic electrical resistor, if an electrical bias is placed across the electrical contacts. An ITD device, unlike conventional DTE devices, will produce heat in a manner similar to an ohmic electrical resistor, rather than merely move heat from one location to another. This may allow ITD devices to act as isothermal heating devices in addition to isothermal cooling devices.

One application of an isothermal heating and cooling ITD device is in the field of electrical energy storage. As shown in FIG. 15, an isothermal ITD energy storage device (“IES-ITD device”) may convert and store electrical energy as thermal energy, and reconvert and release the stored thermal energy through an ITD device as electrical energy when a resistive electrical circuit is placed on the system. Device operation would proceed as follows: electrical energy would be provided by a source (E_{mg}), such as an electrical motor/generator, which would be transferred to the ITD device via the electrical contacts (C₁ and C₂). The ITD device then may generate thermal energy, through electrical carrier recombination and friction in the Active Layer, which may diffuse through the ITD substrate, thermal conductor (T_{c}), and high heat capacity thermal medium (Tₘ) until a thermal energy diffusion equilibrium is reached. This thermal medium may be solid, such as aluminum or copper, or it may be liquid, such as a mixture of water and ethylene glycol common to most radiator fluids. If the electrical energy is no longer added to the ITD device, then the stored thermal energy will remain in thermal equilibrium with the ITD device. This energy may then be released by placing an electrically resistive circuit across the ITD device, similar to the above examples, decreasing the temperature of the Active Layer motivating thermal energy to diffuse through the IES-ITD device to the Active Layer in an attempt to reestablish the thermal diffusion equilibrium. An IES-ITD device may use one or many ITD device(s) in either single layer or multilayer configurations.

An IES-ITD device has many advantages over standard electrical energy storage devices, such as electrochemical batteries. IES-ITD devices may take advantage of existing thermal cooling infrastructure, such as a car radiator, to provide the high heat capacity thermal medium to store electrical energy. IES-ITD devices may provide energy storage densities in excess of 150 Wh/L using a water/ethylene glycol thermal medium, which is greater than typical conventionally heavier nickel metal hydride batteries, and IES-ITD devices may also convert thermal energy generated from a source other than the ITD device, such as a car engine, into useful electrical power.

In addition, IES-ITD devices may power desalination systems by using the passing saltwater as the thermal medium and the generated electricity to promote electrodialysis or freeze desalinization. In the case of electrodialysis the electrical current generated from cooling the salt water may promote the separation of ions from the water. In the case of freeze distillation the electrical energy may assist in physically transporting the ice/water suspension through the device. In addition, unlike other conventional electrically driven desalinization devices, ITD desalination devices may enable electrodialysis and freeze distillation to be combined to take advantage of the decrease in solution temperature to achieve greater efficiencies over conventional designs.

Likewise, ITD devices may be used to replace or supplement radiative cooling systems in vehicles, such as automobiles. A system for increasing the efficiency of a vehicle engine that operates by cooling the engine to generate electrical power may include an ITD device as described above and positioned in thermal communication with a vehicle engine. The ITD device is simultaneously connected in electric communication with the engine, such as to the electrochemical battery, such that heat generated by the vehicle engine is conducted into the ITD device and used to generate charge carriers in the Active Layer, which are subsequently separated by the built-in electric field and isolated by the electron diffusion barriers, and thus provide electric power. Heat conducted into the ITD device is thus transduced into electricity and this process removes heat from the engine, and so operates to cool the engine. Thus, waste heat generated by operation of an internal combustion engine can be transduced into electricity and either used immediately or stored for later use.

While the novel technology has been illustrated and described in detail in the drawings and foregoing description, the same is to be considered as illustrative and not restrictive in character. It is understood that the embodiments have been shown and described in the foregoing specification in satisfaction of the best mode and enablement requirements. It is understood that one of ordinary skill in the art could readily make a nigh-infinite number of insubstantial changes and modifications to the above-described embodiments and that it would be impractical to attempt to describe all such embodiment variations in the present specification. Accordingly, it is understood that all changes and modifications that come within the spirit of the novel technology are desired to be protected.

What is claimed is:

1. A device for simultaneously generating electrical power and cooling, comprising:
an active layer for intrinsically transducing thermal energy into electrical energy;
a first electrical contact having a first work function;
a second electrical contact having a second work function;
a first electron diffusion barrier positioned between and in electric communication with the active layer and the first electrical contact;
a second electron diffusion barrier positioned between and in electric communication with the active layer and the second electrical contact;
wherein the first work function and the second work function are nonidentical;
wherein the transduction of thermal energy into electrical energy yields thermally generated electrical carriers of both positive and negative charge;
wherein thermally generated electrical carriers are separated according to charge to either the first electrical contact or the second electrical contact, thereby lowering the average thermal energy of the active layer.

2. The device of claim 1, wherein the first electron diffusion barrier is the second electron diffusion barrier.

3. The device of claim 1, wherein the electron diffusion barrier is selected from the group including SiO₂, Si₃N₄, SiNₓO₁₋ₓ, SiC, TiO₂, Nb₂O₅, HfO₂, ZrO₂, Ta₂O₅, Fe₂O₃, WOₓ, MgO, Y₂O₃, Al₂O₃, and combinations thereof.

4. The device of claim 1, wherein the electrical contacts are selected from the group including Au, Ag, Ni, Pt, Cr, W, Mn, Mg, Mo, Al, Fe, Ti, Ta, Ce, Hf, Zr, Nb, Th, Pb, Zn, Y, Pd, Ca, C, Li, Cu, NiCr, LiₓAl₁₋ₓ, CaₓAl₁₋ₓ, MgₓAl₁₋ₓ, indium oxide, lanthanum nickel oxide, indium tin oxide, cadmium oxide, cupric oxide, cuprous oxide, zinc oxide, aluminum zinc oxide, copper aluminum oxide, Cs₂CO₃, and combinations thereof.

5. The device of claim 1, wherein the active layer has an electrical current factor between about 1×10¹⁷ and about 1×10²² e/cm² S.

6. The device of claim 1, wherein the active layer is a semiconductive alloy and wherein the semiconductive alloy includes a semiconductor selected from the group including silicon, germanium, tin, and combinations thereof.

7. The device of claim 1, wherein the active layer is selected from the group including germanium tin alloy, Fe₃O₄, Ti₂O₃, and MnO₂.

8. The device of claim 1, wherein the active layer further includes a first material characterized by a first current factor and a second material characterized by a second current factor; wherein the second current factor is substantially higher than the first current factor.

9. The device of claim 1, wherein the active layer is a semiconductor characterized by a bandgap of between about 0.025 eV and about 0.60 eV.

10. The device of claim 1, wherein the electron diffusion barrier is a tunnel barrier and has a thickness of between about 0.8 nm and about 3 nm.

11. The device of claim 1 wherein the active layer is deposited on a substrate.

12. The device of claim 1 and further comprising a copper oxide outer layer for absorbing solar energy to generate thermal energy for the active layer.

13. A device for generating electrical power, comprising:
an active layer for intrinsically transducing thermal energy into electrical energy via the thermal generation of electron-hole pairs;
a first electrical contact having a first work function;
a second electrical contact having a second work function;
a first electron diffusion barrier positioned between and in electric communication with the active layer and the first electrical contact; and
a second electron diffusion barrier positioned between and in electric communication with the active layer and the second electrical contact;
wherein the first work function and the second work function are substantially nonidentical;
wherein thermally generated electrons are separated to the first electrical contact and holes are separated to the second electrical contact; and
wherein the introduction of thermal energy to the active layer increases the rate at which electron-hole pairs are formed.

14. The device of claim 13 wherein the active layer, first and second electrical contacts, first and second electron diffusion barriers define an ITD unit and further comprising a plurality of ITD units positioned adjacent one another to define an ITD stack.

15. The device of claim 14 and further comprising a fan operationally connected to the ITD stack for moving cooled fluid away from the ITD stack and moving warm fluid into thermal contact with the ITD stack.

16. The device of claim 13 wherein at least one of the layers is formed by a process selected from the group including chemical vapor deposition, sputtering, electrochemical deposition, physical vapor deposition, cathodic deposition, anodic deposition, and oxidation.

17. The device of claim 13, wherein the active layer is a semiconductor characterized by a bandgap of between about 0.025 eV and about 0.40 eV.

18. A device for generating electrical power, comprising:
a first active layer for intrinsically transducing thermal energy into electrical energy via the thermal generation of electron-hole pairs;
a second active layer positioned adjacent to and in electrical contact with the first active layer;
a first electrical contact having a first work function;
a second electrical contact having a second work function;
a first electron diffusion barrier positioned between and in electric communication with the first active layer and the first electrical contact; and
a second electron diffusion barrier positioned between and in electric communication with an active layer and the second electrical contact;
wherein the first work function and the second work function are nonidentical;
wherein thermally generated electrons are separated to the first electrical contact and holes are separated to the second electrical contact.

19. The device of claim 18 wherein the first electron diffusion barrier is the second electron diffusion barrier.

20. The device of claim 18 and further comprising a metallic interlayer positioned between the first and second active layers.
